(19) United States
(12) Patent Application Publication
(10) Pub. No.: US 2006/0051507 A1
(43) Pub. Date: Mar. 9, 2006

(54) Electronic device manufacturing chamber and methods of forming the same

(75) Inventors: Shinichi Kurita, San Jose, CA (US); Wendell T. Blonigan, Pleasanton, CA (US); Makoto Inagawa, Palo Alto, CA (US)

Correspondence Address: DUGAN & DUGAN, PC, 55 SOUTH BROADWAY, TARRYTOWN, NY, 10591, US

(73) Assignee: APPLIED MATERIALS, INC.

(21) Appl. No.: 11/145,003

(22) Filed: Jun. 2, 2005

Related U.S. Application Data
(60) Provisional application No. 60/576,902, filed on Jun. 2, 2004.
(60) Provisional application No. 60/587,109, filed on Jul. 12, 2004.

(51) Int. Cl. C23C 16/00

(52) U.S. Cl. 427/248.1; 118/715

(57) ABSTRACT

In a first aspect, a first multi-piece chamber is provided. The first multi-piece chamber includes (1) a central piece having a first side and a second side; (2) a first side piece adapted to couple with the first side of the central piece; and (3) a second side piece adapted to couple with the second side of the central piece. The central piece, the first side piece and the second side piece form a substantially cylindrical inner chamber region when coupled together. Numerous other aspects are provided.

The present application claims priority from U.S. Provisional Patent Application Ser. No. 60/576,902, filed Jun. 2, 2004 and titled “SEMICONDUCTOR DEVICE MANUFACTURING TOOL AND METHODS FOR USING THE SAME” (Docket No. 8840/L) and U.S. Provisional Patent Application Ser. No. 60/587,109, filed Jul. 12, 2004 and titled “ELECTRONIC DEVICE MANUFACTURING TOOL AND METHODS FOR USING THE SAME” (Docket No. 8840/L2). Each of these provisional applications is hereby incorporated by reference herein in its entirety.

### FIELD OF THE INVENTION

The present invention relates generally to flat panel display and/or electronic device manufacturing, and more particularly to an electronic device manufacturing chamber and methods of forming the same.

### BACKGROUND OF THE INVENTION

As substrates used in flat panel displays increase in size, the dimensions of electronic device manufacturing chambers (e.g., processing and/or transfer chambers) used to manufacture the larger flat panel displays also must increase in size. However, the difficulty of manufacturing and transporting such chambers also increases with chamber size due to the overall dimensions and/or weight of the chambers. As such, a need exists for improved electronic device manufacturing chambers used for manufacturing large flat panel displays, as well as for improved methods of transporting such chambers.

### SUMMARY OF THE INVENTION

In certain embodiments, a multi-piece chamber is provided that includes (1) a central piece having a first side and a second side; (2) a first side piece adapted to couple with the first side of the central piece; and (3) a second side piece adapted to couple with the second side of the central piece. The central piece, the first side piece and the second side piece form a substantially cylindrical inner chamber region when coupled together.

In certain embodiments, a multi-piece chamber is provided that includes a central piece having (1) a first open side; (2) a second open side opposite the first open side; (3) a first facet, between the first open side and the second open side, adapted to couple to a chamber and having an opening sized to allow a substrate to pass through the opening; and (4) a second facet opposite the first facet and between the first open side and the second open side. The second facet is adapted to couple to a chamber and has at least two vertically stacked openings each sized to allow a substrate to pass through the opening. The multi-piece chamber also includes (1) a first side piece adapted to couple with the first open side of the central piece and having at least a first facet with an opening sized to allow a substrate to pass through the opening; and (2) a second side piece adapted to couple with the second open side of the central piece and having at least a first facet with an opening sized to allow a substrate to pass through the opening. The opening of the first facet of the first side piece, the opening of the first facet of the second side piece and a first opening of the second facet of the central piece are at substantially the same elevation when the first side piece, the second side piece and the central piece are coupled together.

In certain embodiments, a multi-piece chamber is provided that includes (1) a first piece; and (2) at least a second piece coupled to the first piece so as to form the multi-piece chamber. The dimensions of each of the pieces comply with at least one of ground and air transportation regulations, and an overall dimension of the third multi-piece chamber does not comply with at least one of ground and air transportation regulations.

In certain embodiments, a multi-piece chamber is provided that includes (1) a central piece having a first side, a second side and a bottom having a domed portion; (2) a first side piece adapted to couple with the first side of the central piece; and (2) a second side piece adapted to couple with the second side of the central piece.

In certain embodiments, a multi-piece chamber is provided that includes a central piece having a first side, a second side and a bottom having a domed portion and a flat portion. The flat portion has a first thickness and the domed portion has a second thickness that is less than the first thickness. The multi-piece chamber also includes (1) a first side piece adapted to couple with the first side of the central piece; and (2) a second side piece adapted to couple with the second side of the central piece.

In certain embodiments, a multi-piece chamber is provided that includes a central piece having (1) a first side; (2) a second side; (3) a first facet that includes at least one opening sized to allow a substrate to pass through the opening; and (4) a second facet that includes at least three openings each sized to allow a substrate to pass through the opening. The multi-piece chamber also includes (1) a first side piece adapted to couple with the first side of the central piece; and (2) a second side piece adapted to couple with the second side of the central piece.

In certain embodiments, a multi-piece chamber is provided that includes (1) a central piece having a first side and a second side; (2) a first side piece adapted to couple with the first side of the central piece; and (3) a second side piece adapted to couple with the second side of the central piece. The first side of the central piece includes at least a first notch adapted to allow a substrate to be rotated within the multi-piece chamber and to be transferred from the multi-piece chamber to a chamber coupled to the first side piece of the multi-piece chamber.

In certain embodiments, a multi-piece chamber is provided that includes (1) a central piece having a first side and a second side; (2) a first side piece adapted to couple with the first side of the central piece and having at least one fin structure adapted to reduce movement of a side wall of the first side piece; and (3) a second side piece adapted to couple with the second side of the central piece.

In certain embodiments, a multi-piece chamber is provided that includes (1) a central piece having a first side and a second side; and (2) a first side piece adapted to couple with the first side of the central piece. The first side piece includes at least one support structure adapted to reduce movement of a side wall of the first side piece. The multi-piece chamber also includes a second side piece adapted to couple with the second side of the central piece. The second side piece includes at least one support structure adapted to reduce movement of a side wall of the second side piece. Further, the central piece, the first side piece and the second side piece form a substantially cylindrical inner chamber region when coupled together.

In certain embodiments, a multi-piece chamber is provided that includes (1) a central piece having a first side and a second side; (2) a first side piece adapted to couple with the first side of the central piece; (3) a second side piece adapted to couple with the second side of the central piece; and (4) a lid adapted to cover at least the central piece. The lid includes a flat portion and a plurality of support members adapted to reduce movement of the flat portion in a vertical direction.

In certain embodiments, a multi-piece chamber is provided that includes (1) a central piece having a first side and a second side; (2) a first side piece adapted to couple with the first side of the central piece; (3) a second side piece adapted to couple with the second side of the central piece; and (4) a lid adapted to cover at least the central piece. The lid comprises at least one hatch adapted to provide access to an inner region of the multi-piece chamber without requiring the lid to be removed.

In certain embodiments, a multi-piece electronic device manufacturing chamber is provided that includes (1) determining one or more overall dimensions of an electronic device manufacturing chamber; (2) determining how to divide the electronic device manufacturing chamber into a plurality of pieces such that a dimension of each of the plurality of pieces complies with at least one of ground and air transportation regulations; and (3) manufacturing the plurality of pieces. The overall dimensions of the multi-piece chamber do not comply with at least one of ground and air transportation regulations.

In certain embodiments, a method of transporting a multi-piece chamber is provided that includes (1) transporting a first piece of a plurality of chamber pieces via one of ground and air transportation; (2) transporting a second piece of the plurality of chamber pieces via one of ground and air transportation; and (3) complying with necessary transportation regulations while transporting the first and second pieces. The overall dimensions of the multi-piece chamber violate at least one of ground and air transportation regulations.

In certain embodiments, a method of transporting a multi-piece chamber having a central piece, a first side piece and a second side piece is provided. The method includes (1) placing at least a portion of a vacuum robot in the central piece of the chamber; (2) transporting the central piece via one of ground and air transportation; (3) coupling the first side piece to the second side piece; (4) transporting the first and second side pieces together via one of ground and air transportation; and (5) complying with necessary transportation regulations while transporting the central, first side and second side pieces. The overall dimensions of the multi-piece chamber violate at least one of ground and air transportation regulations.

In certain embodiments, a method for supporting an electronic device manufacturing chamber is provided that includes (1) coupling the electronic device manufacturing chamber to one or more sliding mechanisms of an electronic device manufacturing chamber support; and (2) employing the one or more sliding mechanisms to accommodate electronic device manufacturing chamber expansion, thereby preventing the electronic device manufacturing chamber from shifting out of position on the electronic device manufacturing chamber support.

In certain embodiments, an apparatus for supporting an electronic device manufacturing chamber is provided. The apparatus includes a base frame including (1) one or more support members; and (2) one or more sliding mechanisms. The one or more sliding mechanisms are adapted to couple to the electronic device manufacturing chamber and accommodate electronic device manufacturing chamber expansion, thereby preventing the electronic device manufacturing chamber from shifting out of position on the base frame.

In certain embodiments, an apparatus is provided that includes a unit having (1) a central piece of a multi-piece chamber adapted to couple to a first side piece and a second side piece so as to form the multi-piece chamber; (2) a vacuum robot positioned within the central piece; and (3) a base frame for the central piece coupled to the central piece. Dimensions of the unit comply with at least one of ground and air transportation regulations.

In certain embodiments, an apparatus if provided that includes a unit having (1) a first side piece of a multi-piece chamber; and (2) a second side piece of the multi-piece chamber. The first and second side pieces are adapted to couple to a central piece so as to form the multi-piece chamber. The unit also includes (1) a first base frame piece coupled to the first side piece; (2) a second base frame piece coupled to the second side piece. Dimensions of the unit comply with at least one of ground and air transportation regulations. Numerous other aspects are provided in accordance with these and other aspects of the invention.

Other features and aspects of the present invention will become more fully apparent from the following detailed description, the appended claims and the accompanying drawings.

### BRIEF DESCRIPTION OF THE FIGURES

FIG. 1 is a top view of a first exemplary multi-piece electronic device manufacturing chamber in accordance with some embodiments of the present invention.

FIG. 2A is an exploded isometric view of the first exemplary multi-piece electronic device manufacturing chamber in accordance with some embodiments of the present invention.

FIG. 2B is an isometric view of the first chamber of FIG. 2A when assembled.

FIG. 2C is a top view of the first chamber of FIG. 2A.

FIG. 2D is a side view of the first chamber of FIG. 2A.

FIG. 2E is an isometric view of the first chamber of FIG. 2A employing an alternative lid design.

FIG. 3 is an isometric view of a second exemplary multi-piece electronic device manufacturing chamber in accordance with some embodiments of the present invention.

FIG. 4 is an exploded isometric view of the second exemplary multi-piece electronic device manufacturing chamber in accordance with some embodiments of the present invention.

FIG. 5 is a side view of a first piece of the second exemplary multi-piece electronic device manufacturing chamber, shown in a container, in accordance with some embodiments of the present invention.

FIG. 6 is a side view of a second piece of the second exemplary multi-piece electronic device manufacturing chamber, shown in a container, in accordance with some embodiments of the present invention.

FIG. 7 is an isometric view of an electronic device manufacturing chamber support in accordance with some embodiments of the present invention.

FIG. 8 is an isometric view of an exemplary electronic device manufacturing chamber support in accordance with some embodiments of the present invention.

FIG. 9 is an isometric view of the exemplary electronic device manufacturing chamber support of FIG. 8 in accordance with some embodiments of the present invention.

FIG. 10 is an isometric view of the exemplary electronic device manufacturing chamber support of FIG. 9, shown supporting an electronic device manufacturing chamber.

FIG. 11 is an isometric view of an exemplary base frame/central chamber piece assembly that may be transported as a unit.

FIG. 12 is an isometric view of a side piece/base frame assembly that may be transported as a unit.

### DETAILED DESCRIPTION

With regard to a central transfer chamber, both machining a central transfer chamber “on-site” from a single aluminum block and breaking down a central transfer chamber into a number of elements have been discussed as possible approaches to further scaling transfer chambers. See, for example, “LCD Large-Area Substrate Issues, Substrate Enlargement: Where is the Size Limitation?”, Flat Panel Display 2003 (panel discussion), in which I.D. Kang of Applied Komatsu Technologies (AKT) states:
One equipment alternative would be, if the transfer chamber is further enlarged, to have the machining of a single aluminum block done locally in Asia . . . Another option is to break down the central transfer chamber into a number of elements. Although machining a chamber from a single block of aluminum does guarantee vacuum conditions, it would be possible to make a large transfer chamber composed of elements made from several aluminum blocks and to assemble the structure on site.

A first aspect of the present methods and apparatus relates to an improved method and apparatus for addressing the scalability of large electronic device manufacturing chambers, such as transfer chambers. A second aspect of the present methods and apparatus relates to dynamically supporting an electronic device manufacturing chamber.

### Electronic Device Manufacturing Chamber

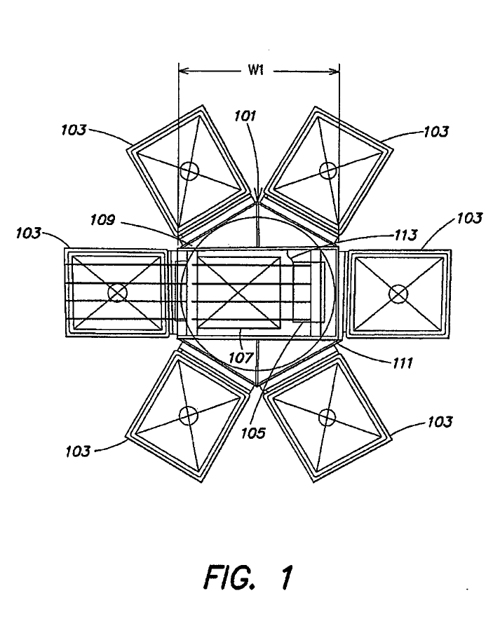

FIG. 1 is a top view of a first exemplary multi-piece electronic device manufacturing chamber in accordance with some embodiments of the present invention. With reference to FIG. 1, the multi-piece electronic device manufacturing chamber 101 is a transfer chamber for transporting substrates during electronic device manufacturing. The transfer chamber is coupled to one or more processing chambers and/or load locks 103 during electronic device manufacturing. The transfer chamber may include an end effector 105 for transporting a substrate 107 among the processing chambers and/or load locks 103 during electronic device manufacturing. A substrate 107 may include, for example, a glass plate, a polymer substrate, a semiconductor wafer or the like.

In accordance with some embodiments of the invention, the transfer chamber 101 may include multiple pieces which are coupled together. More specifically, the transfer chamber 101 may include a first piece 109 (e.g., a first side piece) and a second piece 111 (e.g., a second side piece) coupled to a third piece 113 (e.g., a center piece). The first piece 109 and second piece 111 may each be coupled to the third piece 113 via an O-ring (not separately shown). The first piece 109 and second piece 111 may each be secured to the third piece 113 using securing means, such as screws, bolts, or the like. Although, the multi-piece electronic device manufacturing chamber 101 of FIG. 1 includes three pieces, the multi-piece electronic device manufacturing chamber may include a larger or smaller number of pieces (e.g., 2, 4, 5, 6, etc.).

The width of conventional transfer chambers (e.g., one-piece transfer chambers) is generally limited to about 3 m or less by ground and/or air transportation regulations, transport capacity or building design. For example, a transfer chamber larger than about 3 m may be barred by local regulation from transport in most normal capacity 747 freight airplanes and may be too large to fit through entrance doorways in a standard electronic device fabrication facility. In contrast, in one or more embodiments of the present invention, the width W1 of the multi-piece transfer chamber, when assembled (e.g., the overall width), is 4.2 meters. Therefore, the present electronic device manufacturing chamber 101 can accommodate a larger substrate than can conventional, one-piece transfer chambers. The electronic device manufacturing chamber 101 may be of a larger or smaller width than 4.2 meters.

The shape of the exemplary multi-piece electronic device manufacturing chamber 101 when assembled (e.g., the overall shape) is hexagonal. However, the multi-piece electronic device manufacturing chamber 101 may have other overall shapes (e.g., octagonal if eight chambers are to be coupled to the transfer chamber 101, in which case the first and second pieces 109, 111 may be trapezoidally shaped rather then triangularly shaped as shown).

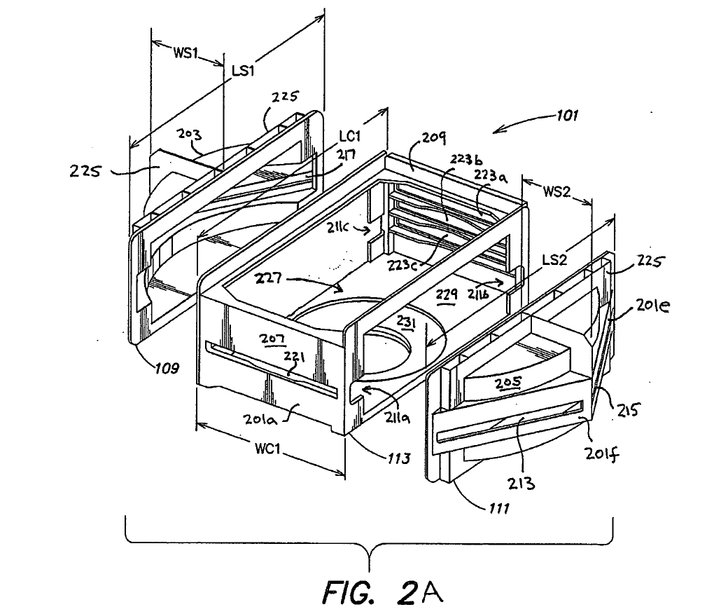

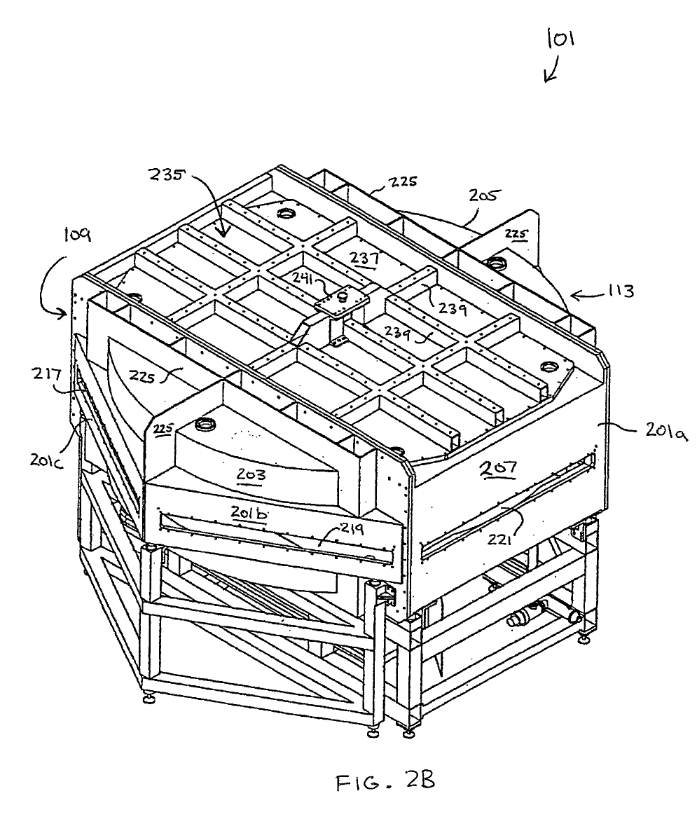

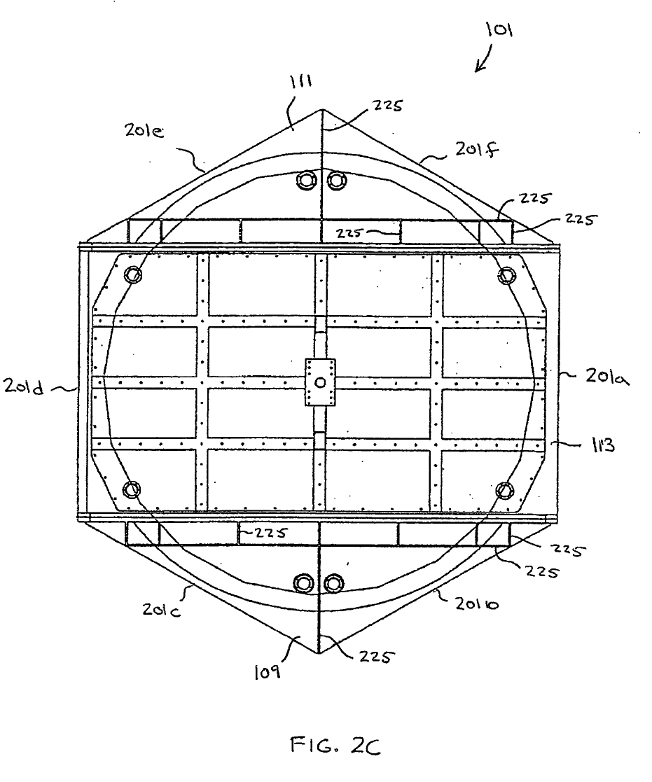

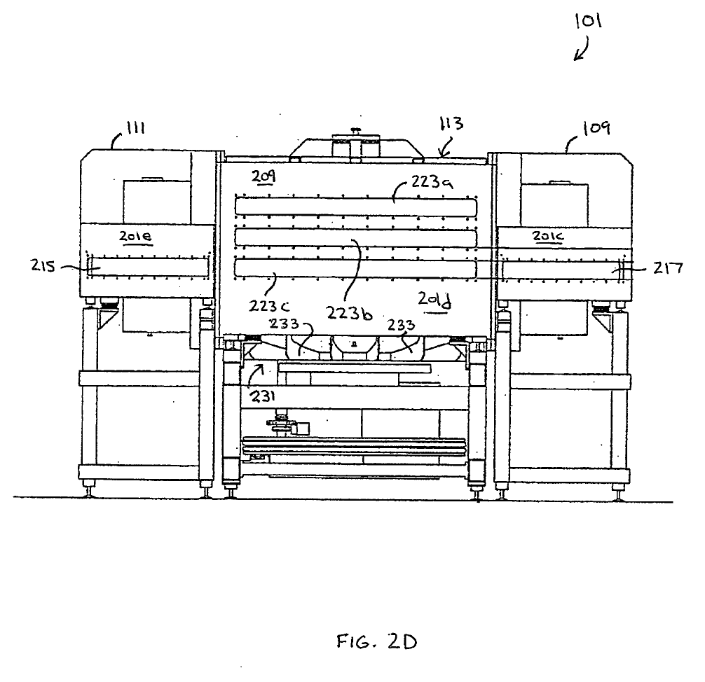

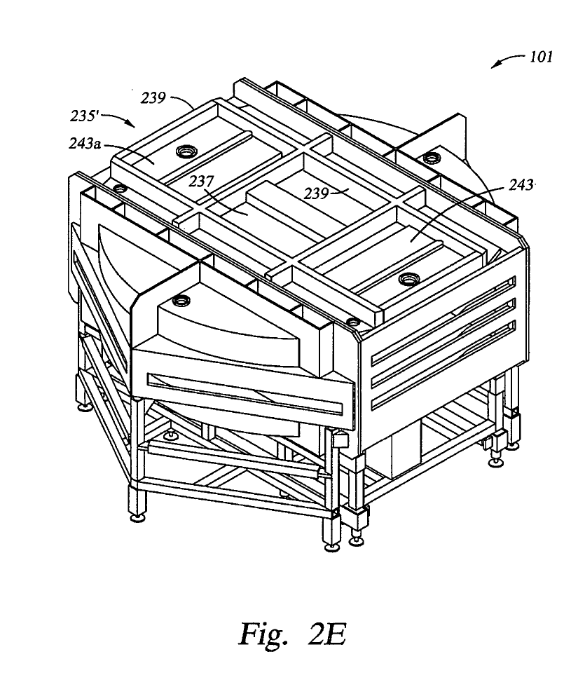

FIG. 2A is an exploded isometric view of the first exemplary multi-piece electronic device manufacturing chamber 101 in accordance with some embodiments of the present invention. Each of the first through third pieces 109-113 may be coupled horizontally to form the multi-piece electronic device manufacturing chamber 101. The length of the first piece 109 is represented by LS1 and the width of the first piece 109 is represented by WS1. The length of second piece 111 is represented by LS2 and the width of the second piece 111 is represented by WS2. The length of the third piece 113 is represented by LC1 and the width of the third piece 113 is represented by WC1.

In one or more embodiments, the width WC1 of the third piece 113 is about 2.4 m and the length LC1 of the third piece 113 is about 4.2 meters. Larger or smaller lengths and/or widths may be employed for the third piece 113. In the embodiment shown, the length LC1 of the third piece 113 serves as the overall width W1 of the chamber 101. As shown, the length LS1 of the first piece 109 and the length LS2 of the second piece 111 are equal to the length LC1 of the third piece 113. However, the length LS1 of the first piece 109 and/or the length LS2 of the second piece 111 may be different. In one embodiment the width WS1 of the first piece 109 and/or the width WS2 of the second piece 111 is about 1.2 meters. However, the width WS1 of the first piece 109 and/or the width WS2 of the second piece 111 may be different (e.g., larger or smaller). (In one particular embodiment, the third piece 113 may have a width that is approximately equal to or less than the width of the first piece 109 plus the width of the second piece 111, although other relationships between the widths of the first, second and third pieces 109, 111 and 113 may be employed). Each piece 109-113 of the multi-piece electronic device manufacturing chamber 101 may be made of, for example, aluminum, stainless steel, or any practicable, relatively inert material suitable for use as a transfer chamber.

Although the overall dimensions of the multi-piece electronic device manufacturing chamber 101 do not comply with ground and/or air transportation regulations, the dimensions of each piece 109-113 of the multi-piece electronic device manufacturing chamber 101 do comply with ground and/or air transportation regulations. More specifically, in the example described above, the overall width W1 of the multi-piece electronic device manufacturing chamber 101 is 4.2 m, which does not comply with ground and/or air transportation regulations. However, the width WS1 of the first piece 109 and the width WS2 of the second piece 111 are 1.2 m and the width WC1 of the third piece 113 is 2.4 m, each of which complies with ground and/or air transportation regulations. (In another embodiment, the width WC1 of the third piece 113 may be about 3 to 3.2 m and the widths WS1, WS2 of the first and second pieces 109, 111 may be about 1.5 to 1.6 m.)

Further, each piece 109-113 of the multi-piece electronic device manufacturing chamber 101 may be fabricated in a conventional machining center or shop. Therefore, a manufacturer of the multi-piece electronic device manufacturing chamber 101 may select one or more of a plurality of conventional machining centers or shops to fabricate the pieces 109-113 of the multi-piece electronic device manufacturing chamber 101. Competition among the plurality of conventional machining centers or shops enables the manufacturer of the multi-piece electronic device manufacturing chamber 101 to obtain a better price. In contrast, the number of machining centers or shops that may fabricate a one-piece electronic device manufacturing chamber with dimensions that can accommodate larger substrates, similar to the multi-piece electronic device manufacturing chamber 101, is limited. This limited number of machining centers or shops results in reduced competition. Due to reduced competition, the manufacturer may pay more for fabrication of such a one-piece chamber than for the multi-piece semiconductor manufacturing chamber 101. Further, because such a one-piece chamber does not comply with ground and/or air transportation regulations, the manufacturer of such a one-piece chamber may need to obtain special accommodations, such as a police escort, an “Oversized Load” sign, or the like, while transporting the device. The multi-piece electronic device manufacturing chamber 101 does not require such accommodations.

Additional features of the first multi-piece electronic device manufacturing chamber 101 will now be described with reference to FIG. 2A, as well as to FIGS. 2B-2D in which FIG. 2B is an isometric view of the first chamber 101 when assembled; FIG. 2C is a top view of the first chamber 101; and FIG. 2D is a side view of the first chamber 101 (illustrating a facet of the first chamber 101 adapted to couple to a triple substrate stacked load lock chamber as described further below).

With reference to FIGS. 2A-2B, the first chamber 101 includes a plurality of facets 201a-f (FIG. 2C). In the embodiment shown, six facets are provided, although a larger or smaller number of facets may be provided (as described previously).

Each facet 201a-f provides a flat sidewall to which a processing chamber, load lock chamber or other chamber may be sealingly coupled (e.g., via an o-ring or other sealing member) as shown, for example, in FIG. 1 with reference to the chambers 103. Despite the presence of the facets 201a-f, the overall structure of the first chamber 101 is substantially cylindrical. For example, as shown in FIGS. 2A-2C, the first (side) piece 109 includes a cylindrical wall 203 into which facets 201b, 201c are formed, and the second (side) piece 111 includes a cylindrical wall 205 into which facets 201e, 201f are formed. The third (central) piece 113 has substantially flat opposing side walls 207, 209 as shown (FIG. 2A) that serve as facets 201a, 201d, respectively.

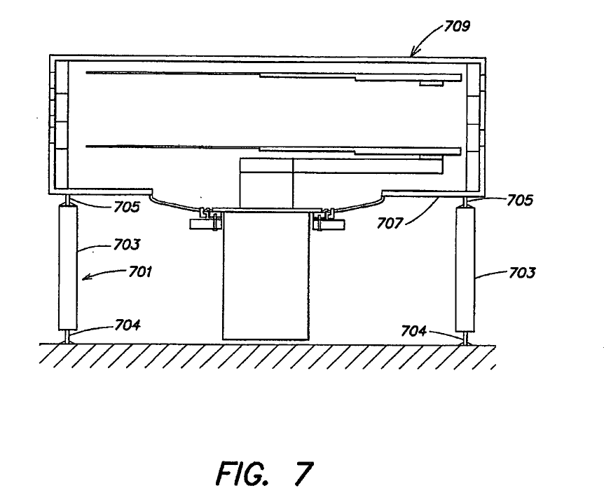

Because of the cylindrical walls 203, 205 of the first and second pieces 109, 111, the interior region of the first chamber 101 is substantially cylindrical (see, for example, FIG. 2A and FIG. 2C). A cylindrical configuration reduces the interior volume of the first chamber 101 while allowing free rotation of a vacuum robot (FIG. 7) located within the first chamber 101. Such rotation may occur, for example, when the robot rotates to transfer substrates between the various chambers coupled to the first chamber 101 (FIG. 1).

To accommodate rotations of a vacuum robot through the third (central) piece 113 of the chamber 101, the third piece 113 includes notched regions 211a-d (see FIG. 2A in which only notches 211a-c are shown). The notches 211a-d also provide additional clearance during substrate transfers through openings (e.g., slit openings) formed in respective facets of the first and the second side pieces 109, 111. That is, the notches 211a-d may provide additional clearance during substrate transfers through openings 213, 215, 217, 219, respectively, which correspond to facets 201f, 201e, 201c, 201b (as shown in FIGS. 2A and 2B).

While facets 201b, 201c, 201e, 201f are shown as having only one opening, each facet may include additional openings (e.g., 2, 3, 4 or more openings). Likewise, the facet 201a of the third (central) piece 113 is shown having a single opening 221 (FIG. 2A), but may include additional openings (e.g., 2, 3, 4, etc.). The facet 201d of the third piece 113 includes three vertically stacked openings 223a-c (FIG. 2A and FIG. 2C), but may include another number of openings (e.g., 1, 2, 4, 5, etc.). In at least one embodiment of the invention, the bottom opening 223c of the facet 201d of the third (central) piece 113 is vertically aligned with the opening 215 of the facet 201e of the second side piece 111 and with the opening 217 of the facet 201c of the first side piece 109 (as shown in FIG. 2D). Note that each opening 213-223c is sized to allow a substrate to pass therethrough. Other configurations may be employed.

Referring again to FIG. 2A-2C, the first and second side pieces 109, 111 include a plurality of fin structures 225, each adapted to provide structural integrity to the first chamber 101. For example, the fin structures 225 may reduce deflection of the cylindrical side/top walls of the first and second side pieces 109, 111 due to pressure differentials between an interior region of the first chamber 101 and any processing chamber coupled thereto, and/or the environment outside of the first chamber 101. Further, the use of the fin structures 225 allows the wall thicknesses of the first and second pieces 109, 111 to be reduced, and reduces the overall weight of the first chamber 101. In one embodiment, the fin structures 225 have a thickness of about 0.55 inches near the outer side/top walls of the first and second side pieces 109, 111 and of about 1.3 inches near the sealing surfaces of the first and second side pieces 109, 111 that contact the central piece 113 (for stainless steel), although other materials and/or thicknesses may be used.

As further shown in FIG. 2A, a bottom 227 of the third (central) piece 113 of the first chamber 101 includes a flat portion 229 and a domed portion 231 (see also FIG. 2D). The domed portion 231 provides improved strength to the bottom 227, because of its domed shape, and reduces the material thickness requirements for the bottom 227. In one exemplary embodiment, the domed portion 231 may have a thickness of about ⅜″ or less while the flat portion 227 may have a thickness of about ¾-1″ or less when stainless steel is employed. Other materials and/or thickness values and/or thickness differences between the flat portion 229 and the domed portion 231 may be used. To further increase the strength of the domed portion 231, fins or similar support structures 233 may be formed below the domed portion 231 as shown in FIG. 2D. The use of the fins 233 may reduce, for example, vertical deflections of the domed portion 231.

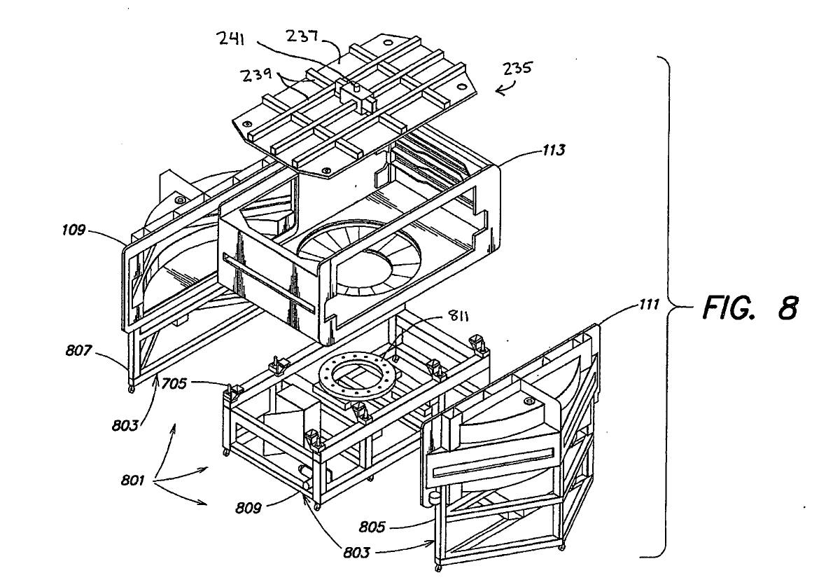

FIGS. 2B-2C and FIG. 8 illustrate a top lid 235 that may be employed with the first chamber 101. For example, the lid 235 may be adapted to seal the third (central) piece 113 of the first chamber (by employing an o-ring or similar sealing element between the lid 235 and the third piece 113).

With reference to FIGS. 2B-2C and FIG. 8, the top lid 235 includes a flat sealing portion 237 that is reinforced with a plurality of support structures, such as beams 239 as shown. The sealing portion 237 may have a thickness similar to that of the flat portion 229 (FIG. 2A) of the bottom 227 of the chamber 101, and the beams 239 provide additional structural support (allowing the thickness and weight of the lid 235 to be reduced). The lid 235 may include a connection location 241 that may be used for lifting and/or lowering the lid 235 relative to the first chamber 101 (e.g., via a crane or the like).

Because of the weight of the lid 235, it may be desirable to provide one or more access hatches or other openings within the lid 235 so that the entire lid 235 need not be removed from the first chamber 101 to gain access to the interior of the first chamber 101 (e.g., for maintenance or other servicing). FIG. 2E is an isometric view of the first chamber 101 employing an alternative lid design 235′ that includes two access hatches 243a-b. Each access hatch 243a-b may be opened to provide access to the interior region of the first chamber 101 without requiring the entire lid 235′ to be removed from the first chamber 101. Other numbers of access hatches may be used (e.g., 1, 3, 4, etc.).

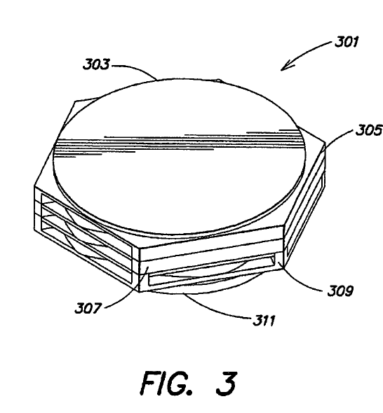

FIG. 3 is an isometric view of a second exemplary multi-piece electronic device manufacturing chamber 301 in accordance with some embodiments of the present invention. The second exemplary multi-piece electronic device manufacturing chamber 301 includes a first through fifth piece 303-311 coupled together. The second exemplary multi-piece electronic device manufacturing chamber 301, however, may include a larger or smaller number of pieces. In contrast to the first exemplary multi-piece electronic device manufacturing chamber 101, each of the pieces of the second exemplary multi-piece electronic device manufacturing chamber 301 may be coupled vertically to form the second exemplary multi-piece electronic device manufacturing chamber 301.

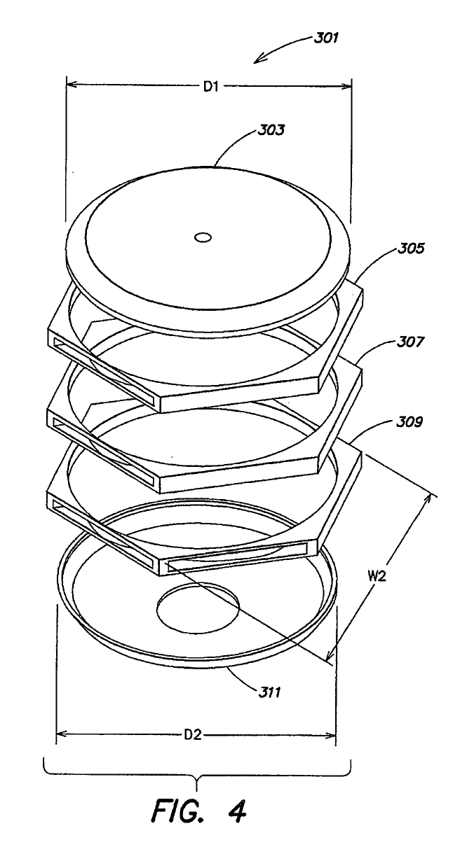

FIG. 4 is an exploded isometric view of the second exemplary multi-piece electronic device manufacturing chamber 301 in accordance with some embodiments of the present invention. A first piece 303 of the second exemplary multi-piece electronic device manufacturing chamber 301 is a domed top lid. The diameter D1 of the domed top lid 303 may be about 4.2 meters, for example. The domed top lid 303 may be made of stainless steel or other materials, and may be manufactured using spinning or another technique.

The domed top lid 303 is coupled to the second piece 305, which is coupled to the third piece 307, which is coupled to the fourth piece 309 of the second exemplary multi-piece electronic device manufacturing chamber 301. The second through fourth pieces 305-309 of the second exemplary multi-piece electronic device manufacturing chamber 301 form a main body of the second exemplary multi-piece electronic device manufacturing chamber 301. The width W2 of each of the second through fourth pieces 305-309 may be about 4.2 meters, for example. Each of the widths of the second 305, third 307 and/or fourth piece 309 may be different, and although each of the second through fourth 305-309 pieces is shown as hexagonal-shaped, other shapes may be employed. In one aspect, each of the second through fourth pieces 305-309 is aluminum, although other materials may be employed. Additionally, a single piece may be employed for the main body.

The fifth piece 311 is a domed bottom lid for the second exemplary multi-piece electronic device manufacturing chamber 301. The fifth piece 311 is coupled to the bottom of the fourth piece 309. Similar to the domed top lid, the diameter D2 of the domed bottom lid may be about 4.2 meters, for example. Other sizes may be used.

To manufacture the multi-piece electronic device manufacturing chamber 101, 301, a user, such as a manufacturer, may employ the inventive method described below. According to the inventive method, one or more overall dimensions of the electronic device manufacturing chamber is determined. More specifically, a manufacturer may need to manufacture a substrate of a required size. Based on the required size, the manufacturer may determine (e.g., design) one or more overall dimensions of an electronic device manufacturing chamber capable of manufacturing such a substrate. If the required substrate size is large enough, the overall dimensions of the chamber will not comply with at least one of ground and air transportation regulations.

Thereafter, the manufacturer, for example, may determine how to divide the electronic device manufacturing chamber into a plurality of pieces such that the dimensions of each of the plurality of pieces complies with at least one of ground and air transportation regulations and at the same time, the structural integrity of the chamber when assembled will be sufficient to perform manufacturing operations. For example, the manufacturer may divide the designed multi-piece electronic device manufacturing chamber into pieces using vertical sectioning, such as with the electronic device manufacturing chamber 101 shown in FIGS. 1-2 or using horizontal sectioning, such as with the electronic device manufacturing chamber 301 shown in FIGS. 3-4. The manufacturer may decide to divide the electronic device manufacturing chamber into pieces using sectioning having other orientations or combinations of orientations.

Thereafter, the plurality of pieces are manufactured. For example, the manufacturer may employ a machining center or shop to fabricate the plurality of pieces. In this manner, the multi-piece electronic device manufacturing chamber 101, 301 is manufactured.

Once the electronic device manufacturing chamber 101, 301 is manufactured, the electronic device manufacturing chamber 101, 301 may be transported, for example, to a customer site. To transport a multi-piece electronic device manufacturing chamber 101, 301, the manufacturer may employ a method of transporting such a chamber in accordance with one or more embodiments of the present invention. For example, a first piece of a plurality of electronic device manufacturing chamber pieces may be transported via one of ground and air transportation. The first piece may be placed in a container that complies with transportation regulations such that the first piece forms an angle with a side (such as a bottom side) of the container. Thus, the first piece may have an actual height or width dimension larger than permitted if it was not placed in the container at such an angle, yet may still fit within a container that complies with transportation regulations. The ability to ship larger pieces allows the inventive multi-piece chamber to be formed from fewer pieces. Therefore, placing the pieces at an angle within the shipping container is preferred, though not required. In some embodiments it may be preferred to manufacture a multi-piece chamber such that a main or central piece is as large as possible and still capable of being fit into a standard size shipping container while the remaining pieces are smaller or as small as possible so that assembly is easier.

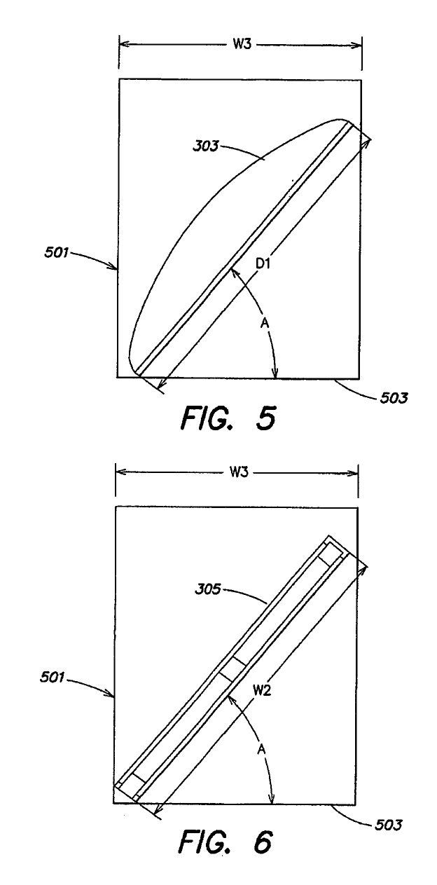

FIG. 5 is a first piece of the second exemplary multi-piece electronic device manufacturing chamber, shown in a container 301, in accordance with some embodiments of the present invention. With reference to FIG. 5, the width W3 of a container 501 may be, for example, 3 meters, which complies with most ground and/or air transportation regulations. A container of a smaller width may be used. The first piece 303 (e.g., the domed top lid) may be placed in the container 501 such that the first piece 303 forms an angle A of about 50 degrees with a side 503, (e.g., a bottom), of the container 501. The first piece 303 may form a larger or smaller angle with the side 503 of the container 501. In one embodiment, the first piece 303 forms an angle A greater than or equal to 50° and less than or equal to 90° with the side 503 of the container 501. Consequently, although the width of the first piece 303 is 4.2 meters, the first piece 303 fits in a container of a smaller width. Thereafter, the container 501 is transported via ground or air transportation. In this manner, the necessary transportation regulations are complied with while transporting the first piece.

Similarly, the second piece 305 of the electronic device manufacturing chamber 301 is transported via one of ground and air transportation. The second piece 305 is placed in a container that complies with transportation regulations such that the second piece 305 forms an angle with the bottom of the container. For example, FIG. 6 is a side view of the second piece 305 of the second exemplary multi-piece electronic device manufacturing chamber 301 in a container 501 in accordance with at least one embodiment of the present invention. With reference to FIG. 6, the second piece 305 is placed in the container 501 in manner similar to the first piece 303.

The overall dimensions of the assembled multi-piece electronic device manufacturing chamber 301 violate at least one of ground and air transportation regulations. For example, the overall width of the electronic device manufacturing chamber 301 is not less than 3 meters, and therefore, does not comply with ground and/or air transportation regulations. Therefore, the first and/or the second pieces are transported separately, for example, in containers 501.

In this manner, a multi-piece electronic device manufacturing chamber 101, 301 may be manufactured at a machining center or shop without the disadvantages (e.g., cost) of manufacturing a similarly-dimensioned one-piece electronic device manufacturing chamber. Further, the multi-piece electronic device manufacturing chamber 101, 301 may be transported to a customer site without the disadvantages (e.g., cost, time, etc.) of transporting a similarly-dimensioned one-piece electronic device manufacturing chamber.

### Supporting an Electronic Device Manufacturing Chamber

FIG. 7 is an isometric view of an electronic device manufacturing chamber support 701 in accordance with the present invention. With reference to FIG. 7, the electronic device manufacturing chamber support 701 includes a base frame 703. One or more portions of the base frame 703 may be attached to a floor (e.g., fixedly via a floor anchor 704).

Note that in a conventional manufacturing chamber support, one or more portions of a base are attached (e.g., fixedly) to the bottom of an electronic device manufacturing chamber. In contrast to a conventional manufacturing chamber support, the electronic device manufacturing chamber support 701 in accordance with some embodiments of the present invention, additionally or alternatively, may include one or more sliding mechanisms 705 for providing dynamic support at the bottom 707 of an electronic device manufacturing chamber 709. The one or more sliding mechanisms 705 may include a slide-able bearing, such as a polytetrafluoroethylene (PTFE)-coated bearing, and an elastomer mount including a load bearing rubber or the like. Other suitable materials may be employed for the one or more sliding mechanisms 705.

Alternatively, the one or more sliding mechanisms 705 may include rollers in place of, or in addition to, sliding bearings. In some embodiments, the electronic device manufacturing chamber 709 may be suspended by vertical, diagonal, and/or horizontal flexible lines such that any expansion may be accommodated by the flexible lines which may have an expansion capacity in excess of the maximum possible expansion of the electronic device manufacturing chamber 709.

The one or more sliding mechanisms 705 are adapted to accommodate thermal or other expansion of the electronic device manufacturing chamber 709. For example, during electronic device manufacturing, heat from adjacent process chambers may cause the temperature of the electronic device manufacturing chamber 101, 301 to exceed 200 or 300 degrees Celsius, which may cause the electronic device manufacturing chamber 709 to expand. The sliding mechanism 705 prevents the electronic device manufacturing chamber 709 from shifting out of position on the electronic device manufacturing chamber support 701 (e.g., on the base frame 703). A sliding mechanism 705 is effective for accommodating any possible amount of electronic device manufacturing chamber expansion, thereby preventing the electronic device manufacturing chamber 709 from shifting off of the electronic device manufacturing chamber support 701 or even just shifting out of position.

FIG. 8 is an isometric view of an exemplary electronic device manufacturing chamber support 801 in accordance with some embodiments of the present invention. With reference to FIG. 8, the exemplary electronic device manufacturing chamber support 801 may be a multi-piece support. More specifically, the exemplary electronic device manufacturing chamber support 801 may include a multi-piece base frame 803. For example, the base frame 803 may include a first piece 805, a second piece 807 and a third piece 809. The base frame 803 may include a larger or smaller number of pieces. The pieces of the exemplary electronic device manufacturing chamber support 801 may correspond to the pieces (e.g., 109-113) of a multi-piece electronic device manufacturing chamber 101 supported by the exemplary electronic device manufacturing chamber support 801.

In the example shown in FIG. 8, the third piece 809 (e.g., a center piece) of the base frame 803 includes eight sliding mechanisms 705. The third piece 809 may include a larger or smaller number of sliding mechanisms 705. As shown in FIG. 7, one or more of the sliding mechanisms 705 may be aligned with (e.g., directly above) a floor anchor 704. However, the sliding mechanisms 705 may be positioned differently. Similarly, the first and second pieces 805, 807 of the base frame 803 may include a plurality of sliding mechanisms 705. Although a multi-piece electronic device manufacturing chamber support 801 is described above, the exemplary electronic device manufacturing chamber support 801 may be a one-piece support.

Note that if thermal expansion causes one or more sliding mechanisms 705 to reach the edge of their individual range, in some embodiments, the other sliding mechanisms 705 will begin to accommodate any further thermal expansion directed at the original sliding mechanisms 705. In other words, once the force applied to move a sliding mechanism 705 to the limit of its individual range encounters a stop frame (described below), the expansion force will be redirected in the opposite direction to be accommodated by other sliding mechanisms 705.

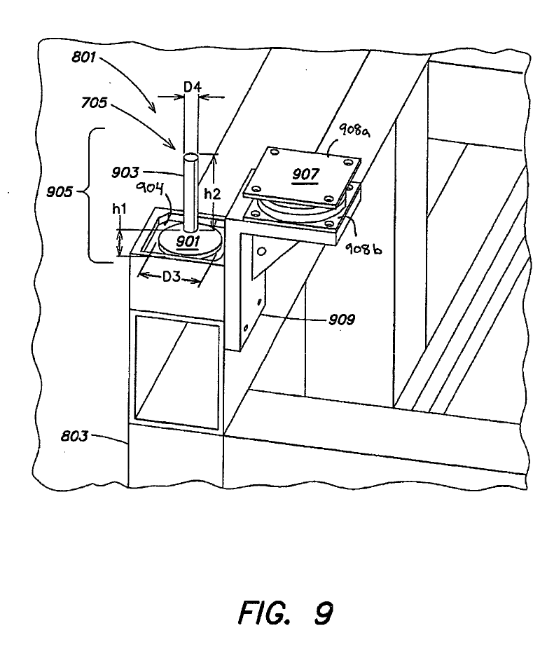

FIG. 9 is a close-up isometric view of the details of a portion of an exemplary electronic device manufacturing chamber support 801 in accordance with some embodiments of the present invention. With reference to FIG. 9, the exemplary electronic device manufacturing chamber support 801 includes one or more sliding mechanisms 705 that may include a slide bearing 905 and an elastomer mount 907.

The slide bearing 905 may include a shaft or threaded rod 903 attached to a foot or slip disk 901. The slip disk 901 may sit in a recess 904 that is coated with, for example, a low friction fluoropolymer resin such as Teflon® made by the Dupont Corporation. The recess or “stop frame” 904 may be square or round or any suitable shape to accommodate a desired range of horizontal motion of the slip disk 901. Likewise, the slip disk 901 may be square or round or any suitable shape to accommodate a desired range of horizontal motion within the recess 904. The slide bearing 905 may be made of steel or any suitable material. In some embodiments, the lower and side surfaces of the slip disk 901 may also be coated with a low-friction fluoropolymer resin such as Teflon® to enable the slide bearing 905 to move freely within the recess 904. Further, the slip disk 901 may include rollers or ball bearings instead of, or in addition to, a low-friction coating. In some embodiments, any suitable moveable bearing may be used in place of the slide bearing 905.

The shaft or threaded rod 903 attached to the slip disk 901 may also be attached to the bottom 707 (FIG. 7) of the electronic device manufacturing chamber 709. The threaded rod 903 may be screwed into a threaded recess in the bottom 707 of the electronic device manufacturing chamber 709 or be attached using any suitable fastening device such as a pin or other fastener.

An elastomer mount 907 may include a flexible material, such as load bearing vulcanized rubber, sandwiched between, and attached to, mounting plates 908a-b. Other suitable flexible materials including metal springs may be used. The mounting plates may be made of steel or any suitable material and may include holes to allow the mounting plates to be attached to the bottom 707 of the electronic device manufacturing chamber 709 and a bracket 909 portion of the base frame 803, respectively.

In operation, the slide bearings 905 may carry the weight of the electronic device manufacturing chamber 709 and also allow the electronic device manufacturing chamber 709 to move within an acceptable range as it expands. At the same time, the elastomer mount 907 may act to effectively bias the electronic device manufacturing chamber 709 toward an ideal position on the electronic device manufacturing chamber support 801. As indicated above, the acceptable range of motion of the electronic device manufacturing chamber 709 may be defined by the sizes of the slip disks 901 and the recesses 904 in which they sit. The position and geometry of the recesses may also effect the range of motion. In some embodiments, the elastomer mount 907 may additionally or alternatively limit the range of motion of the electronic device manufacturing chamber 709.

To further illustrate the invention, example dimensions are provided. Note however, that the following dimensions are merely illustrative of particular embodiments and are merely intended to convey an example of appropriate relative sizes. In some embodiments, the diameter D3 of the slip disk 901 is approximately 100 mm, the recess 904 is approximately 125 mm across, the height h1 of the slip disk 901 is approximately 25 mm, the shaft or threaded rod 903 diameter D4 is approximately 25 mm and the threaded rod 903 height h2 is approximately 137 mm. In some embodiments an M25 bolt (ISO 965-1, Sect. 5, metric fastener size designation) may be used as the threaded rod 903. The sliding mechanism 705 may be shaped and/or dimensioned differently than pictured. In some embodiments, the elastomer mount 907 may deflect or stretch up to approximately 15 mm. The elastomer mount 907 may be shaped and/or dimensioned differently than pictured.

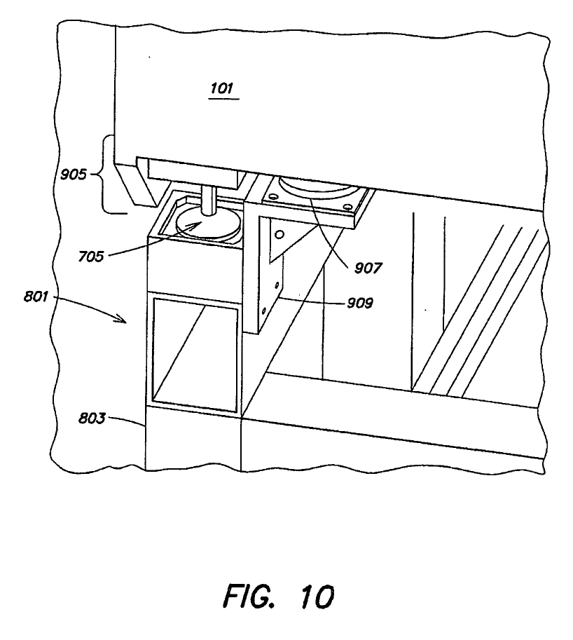

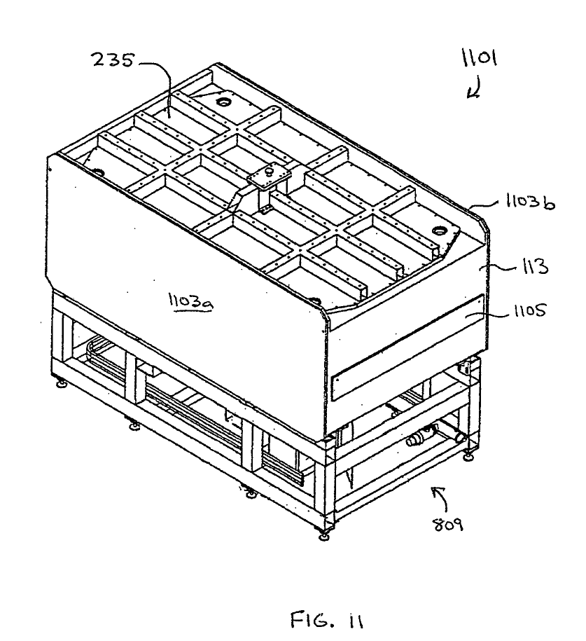

FIG. 10 is an isometric view of the exemplary electronic device manufacturing chamber support 801 of FIG. 9 that is shown supporting an electronic device manufacturing chamber 101. With reference to FIG. 10, the elastomer mount 907 and the slide bearing 905 of each support 801 are coupled to the bottom of an electronic device manufacturing chamber 101.

During electronic device manufacturing, the electronic device manufacturing chamber 101 may grow due to thermal expansion or other forces. More specifically, a portion of the electronic device manufacturing chamber 101 above the support 801 may expand both vertically and horizontally. The growth or expansion of the electronic device manufacturing chamber 101 compresses or stretches the elastomer mounts 907 and moves the slide bearings 705. In this manner, each sliding mechanism 705 accommodates growth or deflection of any expanding portion of the electronic device manufacturing chamber 101. The remaining sliding mechanisms 705 are employed in a similar manner to accommodate the electronic device manufacturing chamber expansion, thereby preventing the electronic device manufacturing chamber 101 from shifting out of position on the electronic device manufacturing chamber support 801. In this manner, the electronic device manufacturing chamber 101 remains substantially balanced and level during electronic device manufacturing. In contrast, thermal expansion of a manufacturing chamber supported by a conventional support, which is only fixedly coupled to the electronic device manufacturing chamber, may cause the electronic device manufacturing chamber to shift out of position with, fall off of, and/or damage the support.

To support an electronic device manufacturing chamber a method for supporting the electronic device manufacturing chamber in accordance with some embodiments of the present invention may be employed. More specifically, the electronic device manufacturing chamber is coupled to one or more sliding mechanisms 705 of an electronic device manufacturing chamber support 801. The one or more sliding mechanisms 705 are employed to accommodate electronic device manufacturing chamber expansion, thereby preventing the electronic device manufacturing chamber from shifting out of position or falling off the electronic device manufacturing chamber support 801. For example, the elastomer mounts 907 of the sliding mechanisms 705 may be stretched or compressed to accommodate electronic device manufacturing chamber expansion.

The foregoing description discloses only exemplary embodiments of the invention. Modifications of the above disclosed apparatus and methods which fall within the scope of the invention will be readily apparent to those of ordinary skill in the art. For instance, although some of the embodiments described above relate to a transfer chamber, the present methods and apparatus may be employed for other types of electronic device manufacturing chambers, such as processing chambers for PVD, CVD or the like. Further, in one or more embodiments, a robot may be inserted (e.g., assembled) into a piece of the multi-piece electronic device manufacturing chamber 101, 301 before the piece is transported to the customer site. For example, a bottom portion of a vacuum robot may be installed in the third (central) piece 809 (FIG. 8) of the frame 803, such as in a base ring 811 of the frame 803, and a top portion of the vacuum robot may be installed in the third (central) piece 113 of the chamber 101. The third piece 113 of the chamber 101 then may be coupled to the third piece 809 of the base frame 803, and the base frame/central chamber piece assembly may be transported as a unit. FIG. 11 is an isometric view of an exemplary base frame/central chamber piece assembly 1101 that may include a vacuum robot (not shown) and that is ready to be transported. In at least one embodiment, prior to shipment, cover units 1103a-b are installed over the open sides of the third (central) piece 113 of the chamber 101, and cover units 1105 are installed over the openings of any facets of the third piece 113. The cover units 1103a-b, 1105 may be formed from aluminum or any other suitable material and may protect the inside of the chamber 101, and/or any components installed therein, during shipment.

In one or more embodiments of the invention, the assembly 1101 is dimensioned to comply with at least one of ground and air transportation regulations. For example, the assembly 1101 may have a height of about 3 m or less.

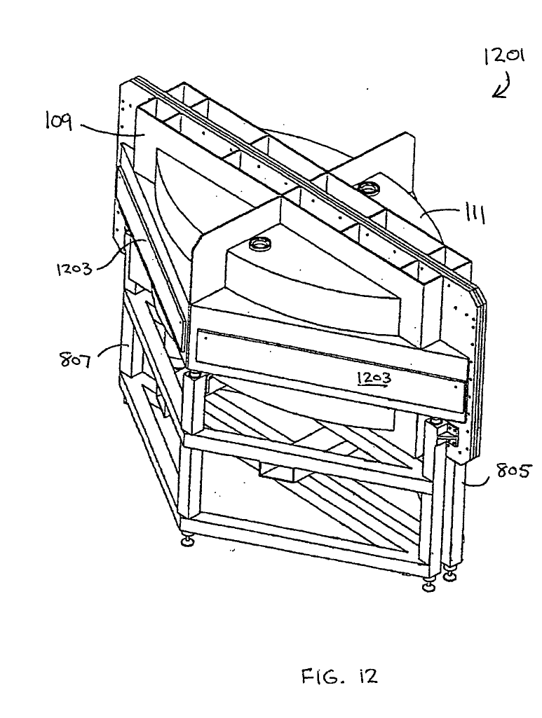

In another embodiment of the invention, the first and second side chamber pieces 109, 111 and the first and second base frame pieces 807, 805 may be assembled and/or transported together as a unit. For example, FIG. 12 is an isometric view of a side piece/base frame assembly 1201 that may be transported as a unit. The assembly 1201 may be formed, for example, by coupling the first side piece 109 of the chamber 101 to the base frame piece 807, by coupling the second side piece 111 of the chamber 101 to the base frame piece 805, and by placing the side piece/base frame assemblies together as shown. The assembly 1201 then may be transported as a unit. Cover units 1203 similar to the cover units 1105 of FIG. 11 may be used to cover any facet openings prior to shipment (e.g., to protect the interior of the chamber pieces).

In one or more embodiments of the invention, the assembly 1201 is dimensioned to comply with at least one of ground and air transportation regulations. For example, the assembly 1201 may have a height of about 3 m or less.

The pieces of the chambers 101, 103 and/or the base frame 803 may be transported using any suitable method. In at least one embodiment, the side pieces 109, 111 of the chamber 101 may be transported using a first mode of transportation (e.g., land, boat, air, etc.), and the central piece 113 of the chamber 101 may be transported using a second mode of transportation (e.g., land, boat, air, etc.). As another example, the first and/or second side piece 109, 111 may be transported via a first truck, and the central piece 113 may be transported using a second truck.

In at least one embodiment of the invention, the vacuum robot may employ a floating seal to isolate the robot from movement of the chamber bottom as shown in FIG. 7 (e.g., by mounting the robot onto the frame of the chamber using a bellows seal) in a manner similar to that described in U.S. patent application Ser. No. 10/601,185, filed Jun. 20, 2003, which is hereby incorporated by reference herein in its entirety.

As shown in FIGS. 2A-2E, the side pieces 109, 111 of the first chamber 101 are each single piece units that do not require a separate lid or bottom. Separate lids and/or bottoms may be employed for one or both of the side pieces 109, 111, but require additional sealing interfaces that may degrade and/or leak.

While the present invention has been described primarily with regard to flat panel displays, it will be understood that the inventive multi-piece chamber may be used to transfer, process and/or manufacture any type of substrate, and may be used to transfer, process and/or manufacture any type of device (e.g., flat panel displays, solar panels and/or cells, etc.).

It will be understood that transportation regulations may vary from country to country (e.g., U.S., Japan, Korea, Taiwan, China, etc.). For example, size limitations or other relevant transportation parameters may vary from country to country. However, the present invention may be adapted/modified to accommodate the particular transportation regulations of any country (and still fall within the spirit and scope of the invention).

In at least one embodiment of the invention, a method of processing a substrate is provided. The method includes the steps of (1) transferring the substrate from a load lock chamber to a multi-piece transfer chamber that includes a central piece, a first side piece, and a second side piece; (2) transferring the substrate from the multi-piece transfer chamber into a processing chamber; (3) depositing at least one film over the substrate; and (4) transferring the substrate to the load lock chamber. The step of transferring the substrate from the multi-piece transfer chamber into a processing chamber may include rotating the substrate through a notch in a sidewall of the central piece of the transfer chamber (as previously described, for example, with reference to FIG. 2A).

The step of transferring the substrate from the load lock chamber to the multi-piece transfer chamber may include elevating or lowering the substrate. For example, if the load lock chamber is adapted to support at least two vertically stacked substrates, the central piece may include a facet having two or more vertically stacked openings (FIG. 2A). A vacuum robot of the transfer chamber may need to raise or lower to transfer substrates to or from the load lock chamber. Likewise, if the load lock chamber is adapted to support at least three vertically stacked substrates, the central piece may include a facet having three or more vertically stacked openings (FIG. 2A). A vacuum robot of the transfer chamber may need to raise or lower to transfer substrates to or from the load lock chamber.

The step of depositing at least one film over the substrate may include depositing at least one film over the substrate by using chemical vapor deposition, physical vapor deposition or any other suitable technique.

Accordingly, while the present invention has been disclosed in connection with exemplary embodiments thereof, it should be understood that other embodiments may fall within the spirit and scope of the invention, as defined by the following claims.

The invention claimed is:

1. A multi-piece chamber comprising:
a central piece having a first side and a second side;
a first side piece adapted to couple with the first side of the central piece; and
a second side piece adapted to couple with the second side of the central piece;
wherein the central piece, the first side piece and the second side piece form a substantially cylindrical inner chamber region when coupled together.

2. The multi-piece chamber of claim 1 wherein central piece, the first side piece and the second side piece form a transfer chamber when coupled together.

3. The multi-piece chamber of claim 1 wherein the central piece has a substantially rectangular shape.

4. The multi-piece chamber of claim 1 wherein the central piece has a length of about 3 meters or greater.

5. The multi-piece chamber of claim 4 wherein the central piece has a width of about 2.4 meters or greater.

6. The multi-piece chamber of claim 1 wherein the central piece includes a bottom having a domed portion.

7. The multi-piece chamber of claim 6 wherein the domed portion is adapted to accommodate a vacuum robot.

8. The multi-piece chamber of claim 6 wherein the domed portion includes at least one support fin adapted to reduce movement of the domed portion in a vertical direction.

9. The multi-piece chamber of claim 8 wherein the domed portion includes a plurality of support fins, each support fin adapted to reduce movement of the domed portion in a vertical direction.

10. The multi-piece chamber of claim 6 wherein the bottom of the central piece includes a flat portion.

11. The multi-piece chamber of claim 10 wherein the flat portion has a first thickness and the domed portion has a second thickness that is less than the first thickness.

12. The multi-piece chamber of claim 11 wherein the first thickness is about 0.75 to 1.0 inches or less and the second thickness is about 0.375 inches or less.

13. The multi-piece chamber of claim 11 wherein both the flat portion and domed portion are formed from stainless steel.

14. The multi-piece chamber of claim 1 wherein the central piece has a first facet and a second facet, and wherein:
the first facet includes at least one opening sized to allow a substrate to pass through the opening; and
the second facet includes at least two openings each sized to allow a substrate to pass through the opening.

15. The multi-piece chamber of claim 14 wherein the second facet includes at least three openings each sized to allow a substrate to pass through the opening.

16. The multi-piece chamber of claim 14 wherein the first facet is adapted to sealingly couple to a processing chamber.

17. The multi-piece chamber of claim 16 wherein the second facet is adapted to sealingly couple to a load lock chamber.

18. The multi-piece chamber of claim 17 wherein the second facet is adapted to sealingly to couple to a load lock chamber that stores at least three substrates stacked vertically, and wherein the second facet has:
a first opening sized to allow a substrate to pass between the central piece and the load lock chamber at a first elevation;
a second opening sized to allow a substrate to pass between the central piece and the load lock chamber at a second elevation; and
a third opening sized to allow a substrate to pass between the central piece and the load lock chamber at a third elevation.

19. The multi-piece chamber of claim 18 wherein:
the first side piece includes at least a first facet having an opening sized to allow a substrate to pass through the opening;
the second side piece includes at least a first facet having an opening sized to allow a substrate to pass through the opening; and
the opening of the first facet of the first side piece, the opening of the first facet of the second side piece and the first opening of the second facet of the central piece are at substantially the same elevation when the first side piece, the second side piece and the central piece are coupled together.

20. The multi-piece chamber of claim 1 wherein the first side of the central piece includes at least a first notch adapted to allow a substrate to be rotated within the multi-piece chamber and to be transferred from the multi-piece chamber to a chamber coupled to the first side piece of the multi-piece chamber.

21. The multi-piece chamber of claim 20 wherein the second side of the central piece includes at least a first notch adapted to allow a substrate to be rotated within the multi-piece chamber and to be transferred from the multi-piece chamber to a chamber coupled to the second side piece of the multi-piece chamber.

22. The multi-piece chamber of claim 1 wherein the first side piece and the second side piece have a first width, and the central piece has a second width that is approximately twice the first width or greater.

23. The multi-piece chamber of claim 1 wherein the first side piece comprises a substantially cylindrical side wall having a plurality of flat facets formed in the side wall.

24. The multi-piece chamber of claim 23 wherein the first side piece includes two facets, each having an opening sized to allow a substrate to pass through the opening.

25. The multi-piece chamber of claim 23 wherein the first side piece includes at least one fin structure adapted to reduce movement of the side wall of the first side piece.

26. The multi-piece chamber of claim 25 wherein the first side piece includes a plurality of fin structures adapted to reduce movement of the side wall of the first side piece.

27. The multi-piece chamber of claim 1 wherein the second side piece comprises a substantially cylindrical side wall having a plurality of flat facets formed in the side wall.

28. The multi-piece chamber of claim 1 further comprising a lid adapted to cover at least the central piece.

29. The multi-piece chamber of claim 28 wherein the lid comprises a flat portion and a plurality of support beams adapted to reduce movement of the flat portion in a vertical direction.

30. The multi-piece chamber of claim 29 wherein the flat portion has a thickness of about 0.75 to 1.0 inches or less.

31. The multi-piece chamber of claim 29 wherein the lid comprises at least one hatch adapted to provide access to an inner region of the multi-piece chamber without requiring the lid to be removed.

32. The multi-piece chamber of claim 31 wherein the lid comprises at least two hatches, each adapted to provide access to an inner region of the multi-piece chamber without requiring the lid to be removed.

33. A multi-piece chamber comprising:
a central piece having:
a first open side;
a second open side opposite the first open side;
a first facet between the first open side and the second open side, the first facet adapted to couple to a chamber and having an opening sized to allow a substrate to pass through the opening; and
a second facet opposite the first facet and between the first open side and the second open side, the second facet adapted to couple to a chamber and having at least two vertically stacked openings each sized to allow a substrate to pass through the opening;
a first side piece adapted to couple with the first open side of the central piece, the first side piece having at least a first facet with an opening sized to allow a substrate to pass through the opening; and
a second side piece adapted to couple with the second open side of the central piece, the second side piece having at least a first facet with an opening sized to allow a substrate to pass through the opening;
wherein the opening of the first facet of the first side piece, the opening of the first facet of the second side piece and a first opening of the second facet of the central piece are at substantially the same elevation when the first side piece, the second side piece and the central piece are coupled together.

34. The multi-piece chamber of claim 33 wherein the opening of the first facet of the central piece is at substantially the same elevation as the first opening of the second facet of the central piece.

35. The multi-piece chamber of claim 33 wherein the central piece, the first side piece and the second side piece form a substantially cylindrical inner chamber region when coupled together.

36. The multi-piece chamber of claim 33 wherein the central piece includes a bottom having a domed portion.

37. The multi-piece chamber of claim 36 wherein the domed portion is adapted to couple to a vacuum robot.

38. The multi-piece chamber of claim 36 wherein the domed portion includes at least one support fin adapted to reduce movement of the domed portion in a vertical direction.

39. The multi-piece chamber of claim 36 wherein the bottom of the central piece includes a flat portion.

40. The multi-piece chamber of claim 39 wherein the flat portion has a first thickness and the domed portion has a second thickness that is less than the first thickness.

41. An apparatus comprising:
an electronic device manufacturing chamber support having one or more sliding mechanisms; and
an electronic device manufacturing chamber coupled to the one or more sliding mechanisms;
wherein the one or more sliding mechanisms accommodate expansion of the electronic device manufacturing chamber and prevent the electronic device manufacturing chamber from shifting out of position on the electronic device manufacturing chamber support.

42. The apparatus of claim 41 wherein the one or more sliding mechanisms accommodate electronic device manufacturing chamber expansion by compressing.

43. A multi-piece electronic device manufacturing chamber, comprising:
a first piece; and
at least a second piece coupled to the first piece, thereby forming the multi-piece electronic device manufacturing chamber;
wherein the dimensions of each of the pieces comply with at least one of ground and air transportation regulations; and
wherein an overall dimension of the multi-piece electronic device manufacturing chamber does not comply with at least one of ground and air transportation regulations.

44. The multi-piece electronic device manufacturing chamber of claim 43 further comprising:
an O-ring between the first piece and the second piece; and
means for coupling the first piece to the at least a second piece.

45. The multi-piece electronic device manufacturing chamber of claim 43 wherein the second piece is coupled horizontally to the first piece.

46. The multi-piece electronic device manufacturing chamber of claim 43 wherein the second piece is coupled vertically to the first piece.

47. An apparatus for supporting an electronic device manufacturing chamber, comprising:
a base frame including:
one or more support members; and
one or more sliding mechanisms adapted to:
couple to the electronic device manufacturing chamber; and
accommodate electronic device manufacturing chamber expansion, thereby preventing the electronic device manufacturing chamber from shifting out of position on the base frame.

48. The apparatus of claim 47 wherein the one or more sliding mechanisms are further adapted to compress in response to electronic device manufacturing chamber expansion.

49. A multi-piece chamber comprising:
a central piece having a first side, a second side and a bottom having a domed portion;
a first side piece adapted to couple with the first side of the central piece; and
a second side piece adapted to couple with the second side of the central piece.

50. The multi-piece chamber of claim 49 wherein the domed portion is adapted to accommodate a vacuum robot.

51. The multi-piece chamber of claim 49 wherein the domed portion includes at least one support fin adapted to reduce movement of the domed portion in a vertical direction.

52. The multi-piece chamber of claim 51 wherein the domed portion includes a plurality of support fins, each support fin adapted to reduce movement of the domed portion in a vertical direction.

53. The multi-piece chamber of claim 49 wherein the bottom of the central piece includes a flat portion.

54. The multi-piece chamber of claim 53 wherein the flat portion has a first thickness and the domed portion has a second thickness that is less than the first thickness.

55. The multi-piece chamber of claim 54 wherein the first thickness is about 0.75 to 1.0 inches or less and the second thickness is about 0.375 inches or less.

56. A multi-piece chamber comprising:
a central piece having a first side, a second side and a bottom having a domed portion and a flat portion, wherein the flat portion has a first thickness and the domed portion has a second thickness that is less than the first thickness;
a first side piece adapted to couple with the first side of the central piece; and
a second side piece adapted to couple with the second side of the central piece.

57. The multi-piece chamber of claim 56 wherein the first thickness is about 0.75 to 1.0 inches or less and the second thickness is about 0.375 inches or less.

58. A multi-piece chamber comprising:
a central piece having:
a first side;
a second side;
a first facet that includes at least one opening sized to allow a substrate to pass through the opening; and
a second facet that includes at least three openings each sized to allow a substrate to pass through the opening;
a first side piece adapted to couple with the first side of the central piece; and
a second side piece adapted to couple with the second side of the central piece.

59. A multi-piece chamber comprising:
a central piece having a first side and a second side;
a first side piece adapted to couple with the first side of the central piece; and
a second side piece adapted to couple with the second side of the central piece;
wherein the first side of the central piece includes at least a first notch adapted to allow a substrate to be rotated within the multi-piece chamber and to be transferred from the multi-piece chamber to a chamber coupled to the first side piece of the multi-piece chamber.

60. The multi-piece chamber of claim 59 wherein the second side of the central piece includes at least a first notch adapted to allow a substrate to be rotated within the multi-piece chamber and to be transferred from the multi-piece chamber to a chamber coupled to the second side piece of the multi-piece chamber.

61. A multi-piece chamber comprising:
a central piece having a first side and a second side;
a first side piece adapted to couple with the first side of the central piece, wherein the first side piece includes at least one fin structure adapted to reduce movement of a side wall of the first side piece; and
a second side piece adapted to couple with the second side of the central piece.

62. The multi-piece chamber of claim 61 wherein the second side piece includes at least one fin structure adapted to reduce movement of a side wall of the second side piece.

63. A multi-piece chamber comprising:
a central piece having a first side and a second side;
a first side piece adapted to couple with the first side of the central piece, wherein the first side piece includes at least one support structure adapted to reduce movement of a side wall of the first side piece; and
a second side piece adapted to couple with the second side of the central piece, wherein the second side piece includes at least one support structure adapted to reduce movement of a side wall of the second side piece;
wherein the central piece, the first side piece and the second side piece form a substantially cylindrical inner chamber region when coupled together.

64. A multi-piece chamber comprising:
a central piece having a first side and a second side;
a first side piece adapted to couple with the first side of the central piece;
a second side piece adapted to couple with the second side of the central piece; and
a lid adapted to cover at least the central piece, wherein the lid comprises a flat portion and a plurality of support members adapted to reduce movement of the flat portion in a vertical direction.

65. The multi-piece chamber of claim 64 wherein the lid comprises at least one hatch adapted to provide access to an inner region of the multi-piece chamber without requiring the lid to be removed.

66. A multi-piece chamber comprising:
a central piece having a first side and a second side;
a first side piece adapted to couple with the first side of the central piece;
a second side piece adapted to couple with the second side of the central piece; and
a lid adapted to cover at least the central piece, wherein the lid comprises at least one hatch adapted to provide access to an inner region of the multi-piece chamber without requiring the lid to be removed.

67. An apparatus comprising:
a unit having:
a first side piece of a multi-piece chamber;
a second side piece of the multi-piece chamber, wherein the first and second side pieces are adapted to couple to a central piece so as to form the multi-piece chamber;
a first base frame piece coupled to the first side piece; and
a second base frame piece coupled to the second side piece;
wherein dimensions of the unit comply with at least one of ground and air transportation regulations.

68. A method of processing a substrate, comprising:
transferring a substrate from a load lock chamber to a multi-piece transfer chamber that includes a central piece, a first side piece, and a second side piece;
transferring the substrate from the multi-piece transfer chamber into a processing chamber;
depositing at least one film over the substrate; and
transferring the substrate to the load lock chamber.

69. The method of claim 68 wherein transferring the substrate from the multi-piece transfer chamber into a processing chamber comprises rotating the substrate through a notch in a sidewall of the central piece of the transfer chamber.

70. The method of claim 68 wherein transferring the substrate from the load lock chamber to the multi-piece transfer chamber includes elevating or lowering the substrate.

71. The method of claim 70 wherein the load lock chamber is adapted to support at least two vertically stacked substrates.

72. The method of claim 70 wherein the load lock chamber is adapted to support at least three vertically stacked substrates.

73. The method of claim 68 wherein depositing at least one film over the substrate comprises depositing at least one film over the substrate by using chemical vapor deposition.

74. The method of claim 68 wherein depositing at least one film over the substrate comprises depositing at least one film over the substrate by using physical vapor deposition.

75. A transfer chamber for a cluster system, comprising:
a first body;
a second body attached at one side of the first body; and
a cover combined with an upper portion of the first body.

76. The chamber according to claim 75, wherein the transfer chamber has a hexagonal pillar shape.

77. The chamber according to claim 75, wherein the first body has a hexahedral shape.

78. The chamber according to claim 77, wherein the first body is a rectangular parallelepiped.

79. The chamber according to claim 78, wherein the second body has a triangular prism shape.

80. The chamber according to claim 78, wherein the second body has a square pillar shape.

81. The chamber according to claim 80, wherein upper and lower sides of the second body have a trapezoid shape.

82. The chamber according to claim 75, wherein the transfer chamber has an octagonal pillar shape.

83. The chamber according to claim 75, wherein an O-ring is interposed between the first body and the second body.

84. The chamber according to claim 75, wherein an O-ring is interposed between the first body and the cover.

85. The chamber according to claim 75, further comprising a third body at another side of the first body facing the second body.

86. The chamber according to claim 85, wherein the third body has the same shape as the second body.

87. A separation-type transfer chamber comprising,
a first body having a first opening on an upper side and a second opening on at least one sidewall;
a cover coupled to the first opening of the first body; and
a second body having a third opening coupled to the second opening of the first body, wherein an upper surface part, a sidewall part, and a bottom surface part are formed as one body, and the surfaces formed as one body are extended to each other.

88. The separation-type transfer chamber as recited in claim 87, characterized in that the first opening of the first body and the cover are coupled via a first coupling member, and the second opening of the first body and the third opening of the second body are coupled via a second coupling member.

89. The separation-type transfer chamber as recited in claim 87, characterized in that the transfer chamber, where the first body and the second body are coupled, has a hexagonal prism shape and consists of the first body of a hexahedron and second bodies of two triangular prisms, and that a structure of any coupling member which can be separated or coupled is excluded between the upper surface part and the sidewall part of the second body.

90. The separation-type transfer chamber as recited in claim 88, characterized in that the transfer chamber, where the first body and the second body are coupled, has a hexagonal prism shape and consists of the first body of a hexahedron and second bodies of two triangular prisms, and that a structure of any coupling member which can be separated or coupled is excluded between the upper surface part and the sidewall part of the second body.
